(19) United States
(12) Patent Application Publication
(10) Pub. No.: US 2025/0391736 A1
(43) Pub. Date: Dec. 25, 2025

(54) Electric Circuit Body and Power Conversion Device

(71) Applicant: Hitachi Astemo, Ltd., Hitachinaka-shi, Ibaraki (JP)

(72) Inventors: Ning TANG, Tokyo (JP); Nobutake TSUYUNO, Tokyo (JP); Yujiro KANEKO, Hitachinaka-shi, Ibaraki (JP)

(21) Appl. No.: 18/878,774

(22) PCT Filed: May 15, 2023
(86) PCT No.: PCT/JP2023/018181

§ 371 Date: Dec. 24, 2024

(30) Foreign Application Priority Data
Jul. 4, 2022 (JP) 2022-108047

(51) Int. Cl. H01L 23/433; H01L 23/31; H01L 23/473; H01L 25/07; H02M 7/00; H02M 7/5387; H10D 80/20

(52) U.S. Cl. CPC H01L 23/4334; H01L 23/3107; H01L 23/473; H01L 25/072; H02M 7/003; H02M 7/5387; H10D 80/251

(57) ABSTRACT

An electric circuit body includes a semiconductor device incorporating a semiconductor element by sealing with a sealing material and having a heat dissipating surface for dissipating heat of the semiconductor element, the heat dissipating surface being formed on at least one surface, a cooling member disposed facing the heat dissipating surface of the semiconductor device and configured to cool the semiconductor element, and a heat conduction member disposed between the semiconductor device and the cooling member, wherein a terminal connected to the semiconductor element protrudes out from at least one side surface of the semiconductor device, and a first interval between the sealing material and the cooling member on the one side surface of the semiconductor device from which the terminal is protruded is narrower than a second interval between the sealing material and the cooling member on the other side surface of the semiconductor device from which the terminal is not protruded.

### TECHNICAL FIELD

The present invention relates to an electric circuit body and a power conversion device.

### BACKGROUND ART

A power conversion device using a switching operation of a semiconductor element has high conversion efficiency, and thus is widely used for consumer use, in-vehicle use, railway use, transformation equipment, and the like. The semiconductor element generates heat by energization. Therefore, a cooling member for cooling a semiconductor element is provided, and a heat conduction member is disposed between the semiconductor device incorporating the semiconductor element and the cooling member disposed to face the semiconductor device. The heat conduction member conducts heat generation from the semiconductor element to the cooling member by bringing the semiconductor device and the cooling member into close contact with each other. Cooling of a semiconductor device is required to have high reliability for maintaining heat dissipation property particularly in in-vehicle applications.

PTL 1 discloses a semiconductor module mounting structure in which a grease reservoir is formed on a surface of a resin sealing portion so as to surround a metal heat sink, and even when the grease moves in a surface direction due to an expansion/contraction cycle in a thickness direction of a semiconductor module, outside air is less likely to enter between the metal heat sink and an insulation sheet.

### CITATION LIST

### Patent Literature

PTL 1: JP 2005-310987 A

### SUMMARY OF INVENTION

### Technical Problem

In the semiconductor device described in PTL 1, measures such as a decrease in insulation property due to the outflow of the heat conduction member are not taken into consideration with respect to the terminal protruding out from the semiconductor device, and the reliability of the device is lowered.

### Solution to Problem

An electric circuit body according to the present invention includes a semiconductor device incorporating a semiconductor element by sealing with a sealing material and having a heat dissipating surface for dissipating heat of the semiconductor element, the heat dissipating surface being formed on at least one surface, a cooling member disposed facing the heat dissipating surface of the semiconductor device and configured to cool the semiconductor element, and a heat conduction member disposed between the semiconductor device and the cooling member, wherein a terminal connected to the semiconductor element protrudes out from at least one side surface of the semiconductor device, and a first interval between the sealing material and the cooling member on the one side surface of the semiconductor device from which the terminal is protruded is narrower than a second interval between the sealing material and the cooling member on the other side surface of the semiconductor device from which the terminal is not protruded.

### Advantageous Effects of Invention

According to the present invention, a highly reliable device that suppresses outflow of a heat conduction member can be provided.

### BRIEF DESCRIPTION OF DRAWINGS

FIG. 1 is a plan view of an electric circuit body according to an embodiment.

FIG. 2 is a cross-sectional view taken along line X-X of the electric circuit body.

FIG. 3 is a cross-sectional perspective view taken along line Y-Y of the electric circuit body.

FIG. 4 is a cross-sectional perspective view taken along line X-X of the electric circuit body.

FIG. 5 is a cross-sectional perspective view taken along line Y-Y of the electric circuit body.

FIG. 6 is a semi-transparent plan view of the semiconductor device.

FIG. 7 is a circuit diagram of the semiconductor device.

FIGS. 8(a) through 8(c) are cross-sectional views for explaining manufacturing steps of the electric circuit body.

FIGS. 9(d) through 9(f) are cross-sectional views for explaining manufacturing steps of the electric circuit body.

FIG. 10 is a cross-sectional view taken along line X-X of an electric circuit body in a comparative example.

FIG. 11 is a cross-sectional view taken along line X-X of an electric circuit body in a first modified example.

FIGS. 12(a) and 12(b) are cross-sectional views taken along line X-X of an electric circuit body in a second modified example.

FIGS. 13(a) and 13(b) are side views of an electric circuit body in a third modified example.

FIG. 14 is a cross-sectional view taken along line X-X of an electric circuit body in a fourth modified example.

FIG. 15 is a cross-sectional view taken along line Y-Y of an electric circuit body in a fifth modified example.

FIG. 16 is a cross-sectional view taken along line Y-Y of an electric circuit body in a sixth modified example.

FIG. 17 is a circuit diagram of a power conversion device using a semiconductor device.

FIG. 18 is an outer appearance perspective view of the power conversion device.

FIG. 19 is a cross-sectional perspective view taken along line XV-XV of the power conversion device.

### DESCRIPTION OF EMBODIMENTS

Hereinafter, embodiments of the present invention will be described with reference to the drawings. The following description and drawings are examples for describing the present invention, and are omitted and simplified as appropriate for the sake of clarity of description. The present invention can be implemented in various other forms. Unless otherwise specified, each component may be singular or plural.

Positions, sizes, shapes, ranges, and the like of the components illustrated in the drawings may not represent actual positions, sizes, shapes, ranges, and the like in order to facilitate understanding of the invention. Therefore, the present invention is not necessarily limited to the position, size, shape, range, and the like disclosed in the drawings.

In a case where there is a plurality of components having the same or similar functions, the description may be made with different subscripts given to the same reference numerals. However, in a case where it is not necessary to distinguish the plurality of components, the description may be made with the subscripts omitted.

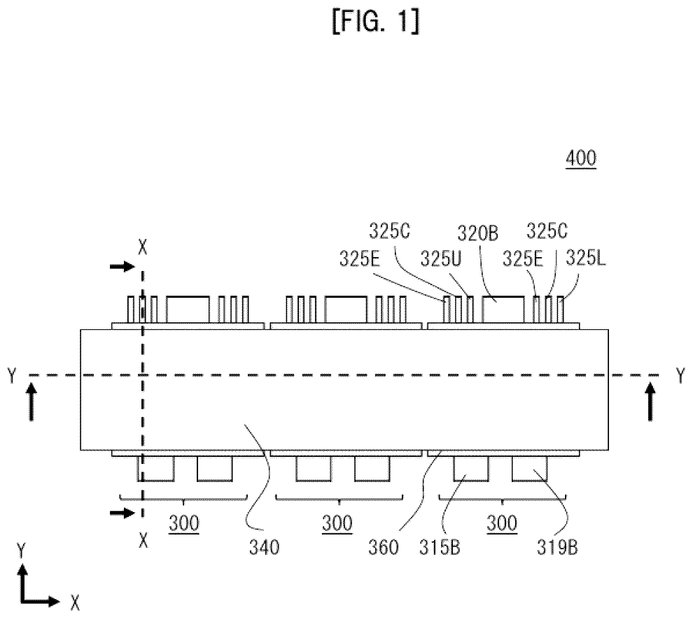

FIG. 1 is a plan view of an electric circuit body 400 according to an embodiment.

The electric circuit body 400 includes a semiconductor device 300 and a cooling member 340. In the example illustrated in FIG. 1, the electric circuit body 400 includes three semiconductor devices 300 provided in parallel.

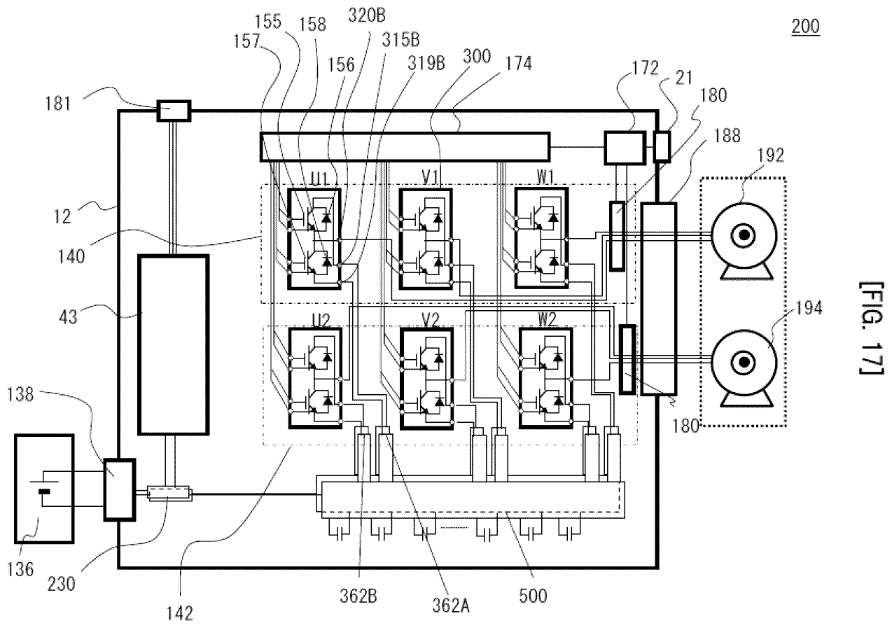

In the semiconductor device 300, semiconductor elements 155 and 157 to be described later are incorporated by being sealed with a sealing material 360. Terminals connected to the semiconductor elements 155 and 157 are led out from the sealing material 360 on the side surface of the semiconductor device 300. These terminals are power terminals through which a large current flows, such as a positive electrode side terminal 315B and a negative electrode side terminal 319B coupled to a capacitor module 500 (see FIG. 17) of a DC circuit, and an AC side terminal 320B coupled to motor generators 192 and 194 (see FIG. 17) of an AC circuit. In addition, the terminals led out from the sealing material 360 on the side surface of the semiconductor device 300 are terminals such as a lower arm gate terminal 325L, a collector sense terminal 325C, an emitter sense terminal 325E, and an upper arm gate terminal 325U. The electric circuit body 400 provided with three semiconductor devices 300 in parallel functions as a power conversion device that converts a DC current and an AC current by switching operations of the semiconductor elements 155 and 157. Note that the number of semiconductor devices 300 included in the electric circuit body 400 is not limited to three, and is arbitrarily set according to various forms of the electric circuit body 400.

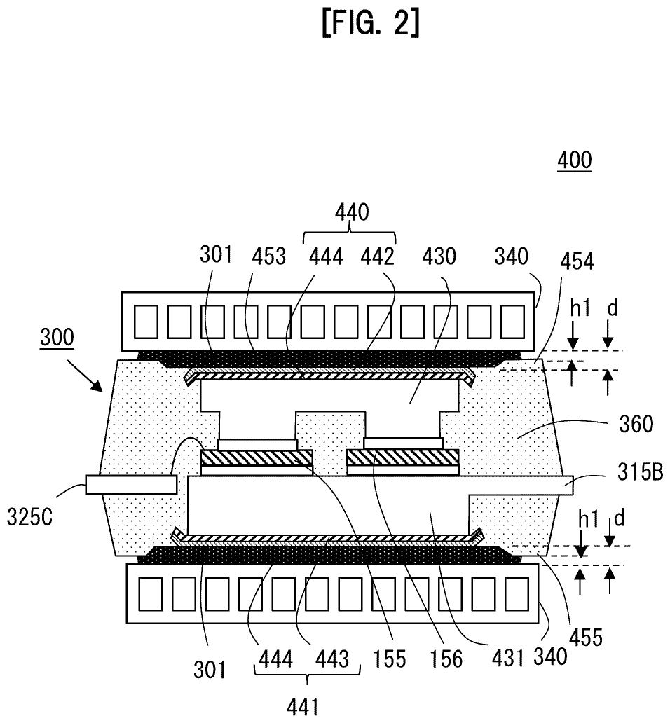

The cooling member 340 is disposed to face a heat dissipating surface 301 (see FIG. 2) of the semiconductor device 300, and cools heat generation by the switching operation of semiconductor elements 155 and 157. Specifically, the cooling member 340 is formed with a flow path through which the refrigerant flows, and cools the heat generation of the semiconductor device 300 by the refrigerant flowing through the flow path. As the refrigerant, water, an anti-freezing fluid in which ethylene glycol is mixed with water, or the like is used. The cooling member 340 is desirably made of aluminum-based material having high thermal conductivity and light weight. The cooling member 340 is manufactured by extrusion molding, forging, brazing, or the like.

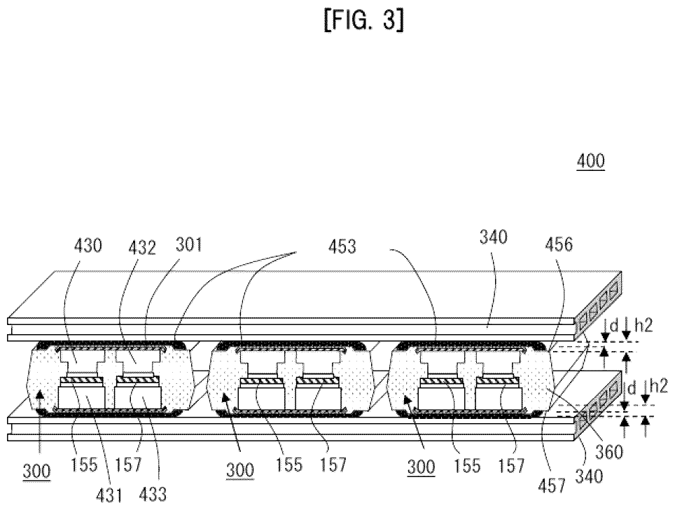

FIG. 2 is a cross-sectional view taken along line X-X of the electric circuit body 400 illustrated in FIG. 1, and FIG. 3 is a cross-sectional perspective view taken along line Y-Y of the electric circuit body 400 illustrated in FIG. 1.

The electric circuit body 400 includes a pressurizing mechanism configured to sandwich and pressurize the cooling members 340 provided on both surfaces of the semiconductor device 300 from both surfaces. Although not illustrated, the pressurizing mechanism is, for example, a mechanism that couples the cooling members 340 on both surfaces to each other with bis or the like to pressurize the cooling members 340 toward the semiconductor device 300 side.

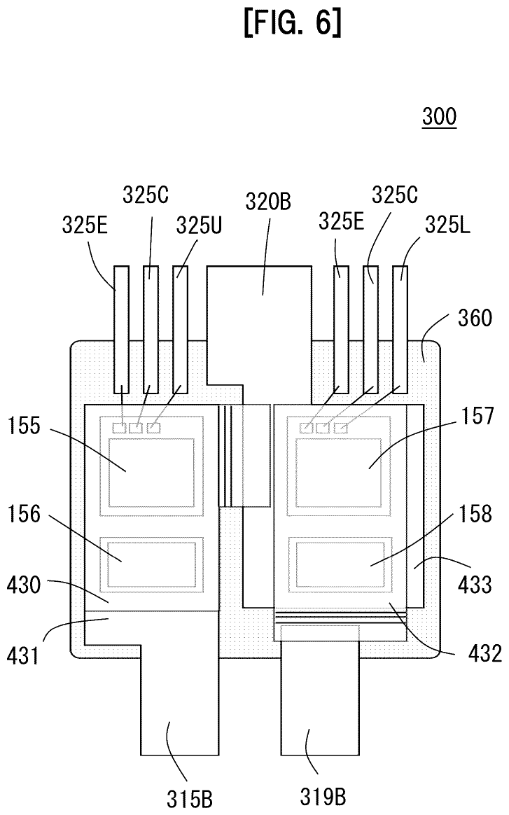

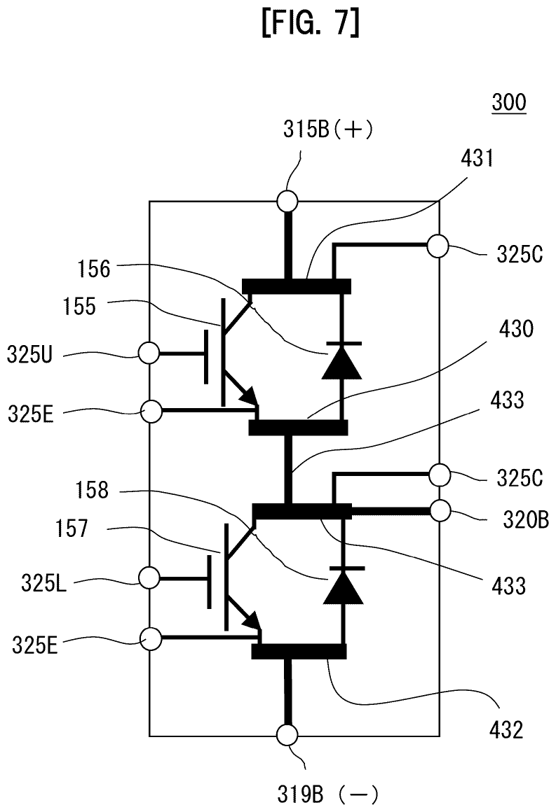

As illustrated in FIG. 2, an active element 155 and a diode 156 are provided as first semiconductor elements forming an upper arm circuit of the power conversion device (see FIGS. 6 and 7 to be described later). When a body diode of the active element 155 is used, the diode 156 may be omitted. A collector side of the first semiconductor element 155 is joined to a second conductor plate 431. For this joining, solder may be used or sintered metal may be used. A first conductor plate 430 is joined to an emitter side of the first semiconductor element 155.

As illustrated in FIG. 3, an active element 157 and a diode 158 are provided as second semiconductor elements forming a lower arm circuit (see FIGS. 6 and 7 to be described later). A collector side of the second semiconductor element 157 is joined to a fourth conductor plate 433. A third conductor plate 432 is joined to an emitter side of the second semiconductor element 157.

Note that Si, SiC, GaN, GaO, C, or the like can be used as the active elements 155 and 157. The active elements 155 and 157 are power semiconductor elements such as insulated gate bipolar transistors (IGBTs) and metal oxide semiconductor field effect transistors (MOSFETS). When MOSFETs are used as the active elements 155 and 157, the diode 156 for the upper arm and the diode 158 for the lower arm are unnecessary.

The conductor plates 430, 431, 432, and 433 are not particularly limited as long as they are materials having high electrical conductivity and thermal conductivity, but it is desirable to use a metal-based material such as a copper-based or aluminum-based material, a composite material of a metal-based material and high thermal conductivity diamond, carbon, ceramic, or the like. These may be used alone, but may be subjected to plating with Ni, Ag, or the like in order to improve the joining property with solder or sintered metal.

As illustrated in FIGS. 2 and 3, the conductor plates 430, 431, 432, and 433 serve as a heat transfer member that transfers heat generated by the semiconductor elements 155, 156, 157, and 158 to the cooling member 340, in addition to a role of energizing current. Since the conductor plates 430, 431, 432, and 433 and the cooling member 340 have different potentials, it is desirable to use insulation sheets 440 and 441 therebetween. The semiconductor elements 155, 156, 157, and 158, the conductor plates 430, 431, 432, and 433, and the insulation sheets 440 and 441 are sealed with a sealing material 360 by transfer mold forming to configure a semiconductor device 300. In order to reduce contact thermal resistance between the semiconductor device 300 and the cooling member 340, a heat conduction member 453 is disposed between the semiconductor device 300 and the cooling member 340.

The resin insulating layers 442 and 443 of the insulation sheets 440 and 441 are not particularly limited as long as they have adhesiveness with a heat sink, but an epoxy resin-based resin insulating layer in which a powdery inorganic filler is dispersed is desirable. This is because the balance between adhesiveness and heat dissipation property is good. The insulation sheets 440 and 441 may be a resin insulating layer alone, but it is desirable to provide a metal foil 444 on the side to come into contact with the heat conduction member 453. In the transfer mold forming step, when the insulation sheets 440 and 441 are mounted on a die, a release sheet or a metal foil 444 is provided on a contact surface of the insulation sheets 440 and 441 with the die in order to prevent adhesion to the die. Since the release sheet has poor thermal conductivity, a step of peeling off the release sheet after transfer molding is required, but in the case of the metal foil 444, it can be used without being peeled off after transfer molding by selecting a copper-based or aluminum-based metal having high thermal conductivity. When the transfer molding is performed including the insulation sheets 440 and 441, the end portions of the insulation sheets 440 and 441 are covered with the sealing material 360, and thus there is an effect that reliability improves.

The heat conduction member 453 is not particularly limited as long as it is a material having high thermal conductivity, but it is preferable to use a high heat conductive material such as a metal, a ceramic, or a carbon-based material in combination with a resin material. This is because the resin material compensates between the high heat conductive material and the high heat conductive material, between the high heat conductive material and the cooling member 340, and between the high heat conduction member and the insulation sheets 440 and 441, and the contact thermal resistance reduces. The resin material is not particularly limited. For example, a material containing a silicone-based resin as a main component and having good electrical insulation property is preferable.

The thermal conductivity of the heat conduction member 453 is about 5 to 8 W/(m·K). The method for measuring the thermal conductivity is not particularly limited. For example, the density, specific gravity, and thermal diffusivity of the heat conduction member 453 are measured, so that it is obtained with the density×specific gravity×thermal diffusivity.

The electric circuit body 400 is subjected to a so-called cooling/heating cycle that repeats heat generation and cooling in accordance with the switching operation of the semiconductor elements 155 and 157. Since the coefficients of thermal expansion of the semiconductor device 300 and the cooling member 340 are different due to this cooling/heating cycle, the heat conduction member 453 tends to be compressed and flow out to the outside of the semiconductor device 300.

As illustrated in FIG. 2, in the semiconductor device 300, terminals 315B and 325C connected to the semiconductor elements 155, 156, 157, and 158 protrude out from both side surfaces of the semiconductor device 300. On the sealing material 360 on both side surfaces of the semiconductor device 300 from which the terminals 315B and 325C are protruded, convex portions 454 and 455 that protrude out than the surface of the heat dissipating surface 301 of the semiconductor device 300 are formed. An interval between the top of the convex portion 454 on the emitter side and the cooling member 340 is a first interval h1. Similarly, an interval between the top of the convex portion 455 on the collector side and the cooling member 340 is the first interval h1.

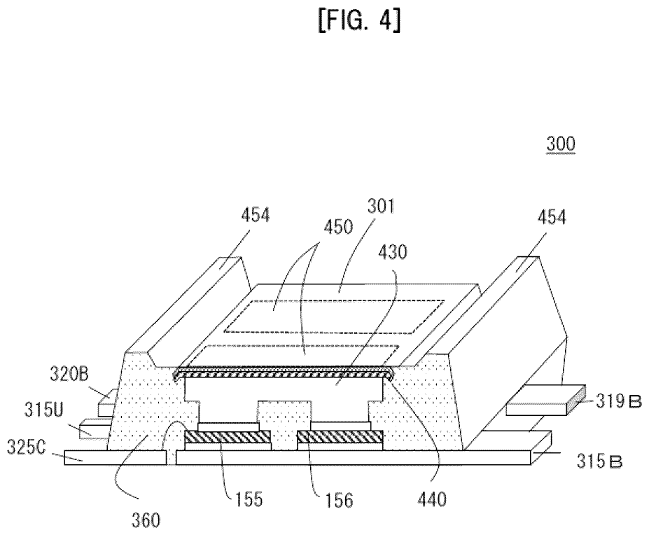

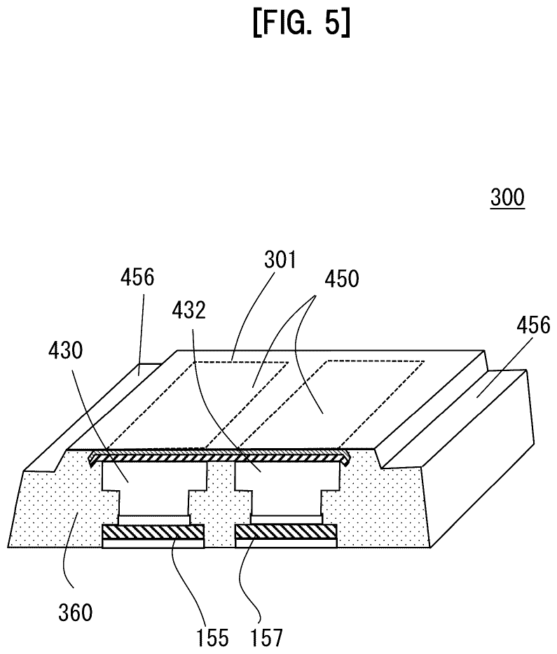

The thickness d of the heat conduction member 453 is a thickness in the stacking direction of the semiconductor device 300 and the cooling member 340 on the emitter side, and is a thickness in the stacking direction of the semiconductor device 300 and the cooling member 340 on the collector side. The heat conduction member 453 is disposed on the heat dissipating surface 301 including a projection region 450 (see FIGS. 4 and 5) of the conductor plates 430, 432 in the stacking direction of semiconductor device 300 and cooling member 340, and the thickness d of the heat conduction member 453 is a thickness of at least a portion disposed on the heat dissipating surface 301.

As illustrated in FIG. 3, concave portions 456 and 457 recessed from the surface of the heat dissipating surface 301 of the semiconductor device 300 are formed in the sealing material 360 on both side surfaces of the semiconductor device 300 from which the terminals 315B and 325C are not protruded. An interval between the bottom of the concave portion 456 on the emitter side and the cooling member 340 is a second interval h2. Similarly, an interval between the bottom of the concave portion 457 on the collector side and the cooling member 340 is the second interval h2.

The first interval h1 between the top of the convex portion 454 on the emitter side and the cooling member 340 or the first interval h1 between the top of the convex portion 455 on the collector side and the cooling member 340 is less than or equal to the thickness d of the heat conduction member 453. Here, when the second interval h2 between the sealing material 360 and the cooling member 340 on the side surface of the semiconductor device 300 from which the terminals 315B and 325C are not protruded is wider than the thickness d, the first interval h1 and the thickness d of the heat conduction member 453 may be equal.

The second interval h2 between the bottom of the concave portion 456 on the emitter side and the cooling member 340 or the second interval h2 between the bottom of the concave portion 457 on the collector side and the cooling member 340 is greater than or equal to the thickness d of the heat conduction member 453. Here, when the first interval h1 is narrower than the thickness d of the heat conduction member 453, the second interval h2 and the thickness d of the heat conduction member 453 may be equal.

As described above, in the electric circuit body 400, the first interval h1 between the sealing material 360 and the cooling member 340 on one side surface of the semiconductor device 300 from which the terminal is protruded is narrower than the second interval h2 between the sealing material 360 and the cooling member 340 on the other side surface of semiconductor device 300 from which the terminal is not protruded. As a result, even if the semiconductor device 300 repeats expansion and contraction due to the cooling/heating cycle, the heat conduction member 453 is likely to run out to the side where the terminal is not protruded and is less likely to run out to the side where the terminal is protruded. Therefore, when the cooling/heating cycle is repeated, the heat conduction member 453 is likely to run out to the side where the terminal is not protruded, in which case, there is an effect of filling the gap between the adjacent semiconductor devices 300 and further fixing the semiconductor devices 300. Since the heat conduction member 453 is less likely to run out to the side where the terminal is protruded, it is possible to prevent the heat conduction member 453 that ran out from adhering to the terminals and the insulation property between the terminals from deteriorating due to a migration phenomenon or the like.

FIG. 4 is a cross-sectional perspective view taken along line X-X of the electric circuit body 400 illustrated in FIG. 1, and FIG. 5 is a cross-sectional perspective view taken along line Y-Y of the electric circuit body 400 illustrated in FIG.

1. These cross-sectional perspective views illustrate the emitter side of the semiconductor device 300 in a state where the cooling member 340 and the heat conduction member 453 are removed from the electric circuit body 400.

The heat conduction member 453 is disposed so as to cover the heat dissipating surface 301 including a projection region 450 of the conductor plates 430, 432 in the stacking direction of the semiconductor device 300 and the cooling member 340 illustrated in FIG. 4. The heat dissipating surface 301 of the semiconductor device 300 is a surface including at least the projection region 450. As illustrated in FIG. 4, on the sealing material 360 on the side surface of the semiconductor device 300 on the terminals 315B and 325C side, a convex portion 454 protruding from the surface of the heat dissipating surface 301 of the semiconductor device 300 is formed outside the range of the heat dissipating surface 301. In a manufacturing step to be described later, the convex portion 454 is formed by providing a concave portion in the die when forming the sealing material 360. The shape of the convex portion 454 is not particularly limited. For example, a trapezoid having a long lower side is easy to manufacture. In addition, in order to secure the insulation distance, it is desirable to have a creepage distance of greater than or equal to 1 mm between the area along the convex portion 454 on the projection region 450 side and the outer peripheries of the insulation sheets 440 and 441.

As illustrated in FIG. 5, the concave portion 456 recessed from the surface of the heat dissipating surface 301 of the semiconductor device 300 is formed in the sealing material 360 on the side surface of the semiconductor device 300 from which the terminals 315B and 325C are not protruded. In a manufacturing step to be described later, the concave portion 456 is formed by providing a convex portion in the die when forming the sealing material 360. The shape of the concave portion 456 is not particularly limited. For example, a trapezoid having a short lower side is easy to manufacture. In addition, in order to secure the insulation distance, it is desirable to have a creepage distance of greater than or equal to 1 mm between the area along the concave portion 456 on the projection region 450 side and the outer peripheries of the insulation sheets 440 and 441.

FIG. 6 is a semi-transparent plan view of the semiconductor device 300. FIG. 7 is a circuit diagram of the semiconductor device 300.

As illustrated in FIGS. 6 and 7, the positive electrode side terminal 315B is output from the collector side of an upper arm circuit, and is connected to a positive electrode side of the battery or the capacitor. The upper arm gate terminal 325U is output from the gate of the active element 155 of the upper arm circuit. A negative electrode side terminal 319B is output from an emitter side of a lower arm circuit, and is connected to a negative electrode side of the battery or the capacitor or the GND. The lower arm gate terminal 325L is output from the gate of the active element 157 of the lower arm circuit. An AC side terminal 320B is output from the collector side of the lower arm circuit and is connected to a motor. When a neutral point is grounded, the lower arm circuit is connected not to the GND but to the negative electrode side of the capacitor.

The emitter sense terminal 325E of the upper arm is output from the emitter of the active element 155 of the upper arm circuit, and the emitter sense terminal 325E of the lower arm is output from the emitter of the active element 157 of the lower arm circuit. The collector sense terminal 325C of the upper arm is output from the collector of the active element 155 of the upper arm circuit, and the collector sense terminal 325C of the lower arm is output from the collector of the active element 157 of the lower arm circuit.

In addition, a conductor plate (upper arm circuit emitter side) 430 and a conductor plate (upper arm circuit collector side) 431 are disposed above and below the active element 155 and the diode 156 of the power semiconductor element (upper arm circuit). A conductor plate (lower arm circuit emitter side) 432 and a conductor plate (lower arm circuit collector side) 433 are arranged above and below the active element 157 and the diode 158 of the power semiconductor element (lower arm circuit).

The semiconductor device 300 of the present embodiment has a 2 in 1 structure, which is a structure in which two arm circuits of the upper arm circuit and the lower arm circuit are integrated into one module. In addition, a structure in which a plurality of upper arm circuits and lower arm circuits are integrated into one module may be used. In this case, the number of output terminals from the semiconductor device 300 can be reduced and the size can be reduced.

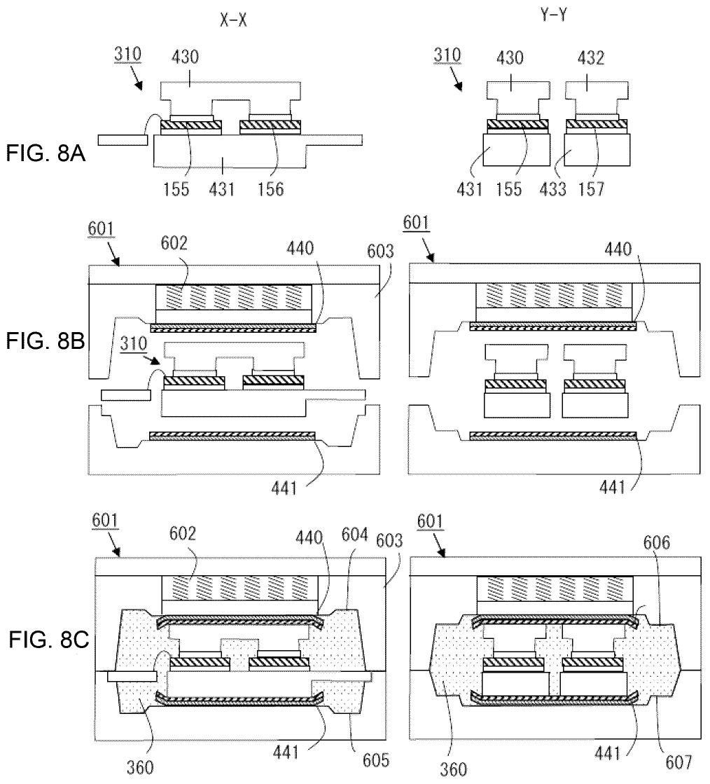

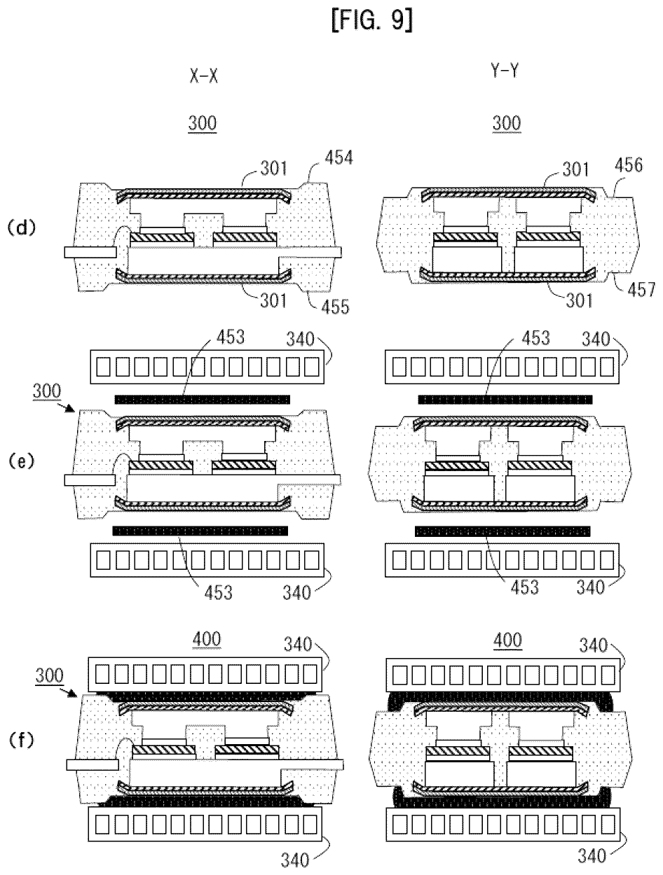

FIGS. 8(a) through 8(c) and FIGS. 9(d) through 9(f) are cross-sectional views for explaining a manufacturing step of the electric circuit body 400. A cross-sectional view taken along line X-X is illustrated on the left side of each drawing, and a cross-sectional view of one semiconductor device 300 taken along line Y-Y is illustrated on the right side of each drawing.

FIG. 8(a) illustrates a solder connecting step and a wire bonding step. The collector side of the semiconductor element 155 and the cathode side of the semiconductor element 156 are connected to the second conductor plate 431, and the gate electrode, the emitter electrode, and the collector electrode of the semiconductor element 155 are connected to the gate terminal 325U, the emitter sense terminal 325E, and the collector sense terminal 325C of the upper arm, respectively, by wire bonding. Furthermore, the emitter side of the semiconductor element 155 and the anode side of the semiconductor element 156 are connected to the first conductor plate 430 to produce the circuit body 310 on the upper arm side. Similarly, the collector side of the semiconductor element 157 and the cathode side of the semiconductor element 158 are connected to the fourth conductor plate 433, and the gate electrode, the emitter electrode, and the collector electrode of the semiconductor element 157 are connected to the gate terminal 325L, the emitter sense terminal 325E, and the collector sense terminal 325C of the lower arm, respectively, by wire bonding. Furthermore, the emitter side of the semiconductor element 157 and the anode side of the semiconductor element 158 are connected to the third conductor plate 432 to produce the circuit body 310 on the lower arm side. However, in FIG. 8(a), only the circuit body 310 on the upper arm side is illustrated, and the circuit body 310 on the lower arm side is not illustrated.

FIGS. 8(b) through 8(c) illustrate a transfer molding step.

In the transfer molding step, a transfer molding device 601 includes a spring 602 and a die 603, and further includes a mechanism for vacuum adsorbing the insulation sheets 440 and 441 and a vacuum degassing mechanism. As illustrated in FIG. 8(b), the insulation sheets 440 and 441 are temporarily placed in a die 603 heated to a constant temperature state of 175° C. in advance, and the insulation sheets 440 and 441 are held by vacuum adsorption. The circuit body 310 preheated to 175° C. in advance is set in the die 603 at a position away from the insulation sheets 440 and 441.

Next, as illustrated in FIG. 8(c), the upper and lower dies 603 are clamped. At this time, the insulation sheets 440 and 441 and the conductor plates 430 and 431 are pressurized and brought into close contact with each other by the spring 602. Next, the die cavity is vacuum exhausted. When vacuum exhaustion to less than or equal to a predetermined atmospheric pressure is completed, the packing is further crushed, and the upper and lower dies 603 are completely clamped. At this time, the insulation sheets 440 and 441 and the circuit body 310 are in contact with each other. In a vacuum state, the insulation sheets 440 and 441 and the circuit body 310 come into contact with each other and come into close contact with each other by pressurization force of the spring 602, so that they can be brought into close contact with each other without involving voids. Then, the sealing material 360 is injected into the die cavity. Note that the peripheral end portions of the insulation sheets 440 and 441 are buried in the sealing material 360.

Here, in the die 603, as illustrated in a cross-sectional view taken along line X-X, the concave portions 604 and 605 further include convex portions 606 and 607 as illustrated in a cross-sectional view taken along line Y-Y. As described with reference to FIG. 2, the concave portions 604 and 605 form the convex portions 454 and 455 protruding out from the surface of the heat dissipating surface 301 of the semiconductor device 300. As described with reference to FIG. 3, the convex portions 606 and 607 form the concave portions 456 and 457 recessed from the surface of the heat dissipating surface 301 of the semiconductor device 300. Thereafter, the semiconductor device 300 in which the sealing material 360 is sealed is taken out from the transfer molding device 601, and post-curing is performed at 175° C. for 2 or more hours.

FIG. 9(d) illustrates the semiconductor device 300 taken out from the transfer molding device 601. In the semiconductor device 300, the convex portions 454 and 455 protruding out from the heat dissipating surface 301 are formed on the side surface of the semiconductor device 300 from which the terminal is protruded out. Furthermore, the concave portions 456 and 457 recessed from the surface of the heat dissipating surface 301 are formed on the side surface from which the terminal is not protruded out.

FIG. 9(e) illustrates an applying step. The heat conduction member 453 is applied to the cooling member 340.

FIG. 9(f) illustrates a close contact/curing step. The cooling member 340 to which heat conduction member 453 is applied is brought into close contact with the semiconductor device 300. Then, the cooling member 340 is pressed against the semiconductor device 300 by way of the heat conduction member 453, and the heat conduction member 453 is cured to produce the electric circuit body 400. As a result, the interval between the convex portions 454 and 455 and the cooling member 340 and the interval between the concave portions 456 and 457 and the cooling member 340 are set to the intervals described with reference to FIGS. 2 and 3.

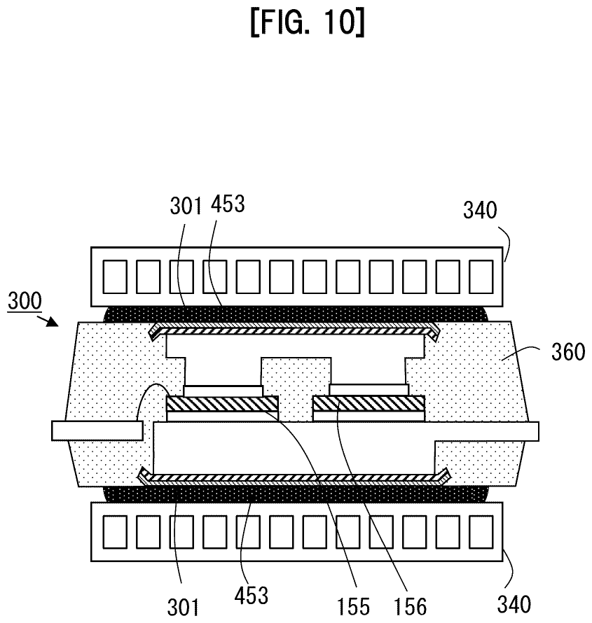

FIG. 10 is a cross-sectional view taken along line X-X of an electric circuit body 400 in a comparative example. This comparative example shows an example of a case where the present embodiment is not applied for comparison with the present embodiment.

As illustrated in FIG. 10, an interval between the sealing material 360 of the semiconductor device 300 and the cooling member 340 on the side surface of semiconductor device 300 is the same as an interval between the heat dissipating surface 301 of the semiconductor device 300 and the cooling member 340. Therefore, there is a possibility that the heat conduction member 453 is compressed and the heat conduction member 453 flows out from the side surface of the semiconductor device 300 to the outside by the cooling/heating cycle. When the heat conduction member 453 runs out to the side where the terminal is protruded, the heat conduction member 453 that ran out adheres to the terminal, thus deteriorating the insulation property between the terminals due to the migration phenomenon or the like.

In the present embodiment, as described with reference to FIGS. 2 and 3, the first interval h1 between the sealing material 360 and the cooling member 340 on one side surface of the semiconductor device 300 from which the terminal is protruded is narrower than the second interval h2 between the sealing material 360 and the cooling member 340 on the other side surface of the semiconductor device 300 from which the terminal is not protruded. As a result, the heat conduction member 453 is suppressed from running out to the side where the terminal is protruded.

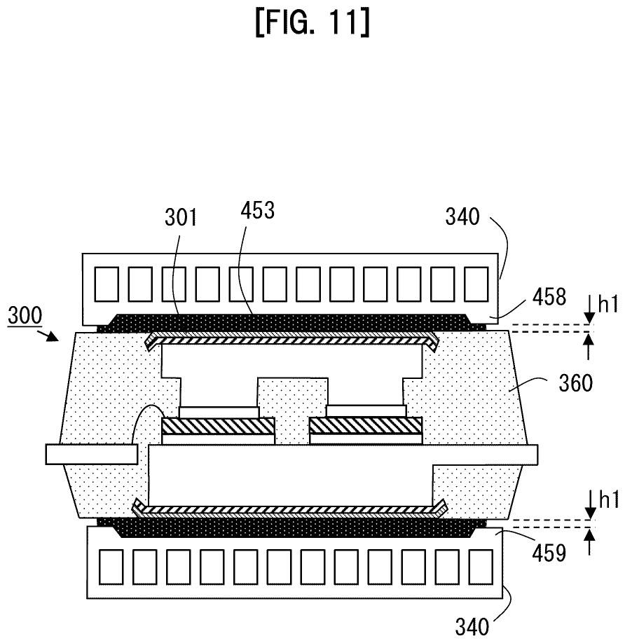

FIG. 11 is a cross-sectional view taken along line X-X of an electric circuit body 400 in a first modified example. Note that a cross-sectional view taken along line Y-Y of the electric circuit body 400 is similar to that of FIG. 3.

In the embodiment illustrated in FIG. 2, the convex portions 454 and 455 are formed on the sealing material 360 on one side surface of the semiconductor device 300 from which the terminal is protruded. In the first modified example, as illustrated in FIG. 11, the convex portions 458 and 459 facing the sealing material 360 are formed at the end portion of the cooling member 340 on the outer side of the heat dissipating surface 301. The first interval h1 which is an interval between the top of the convex portions 458 and 459 and the sealing material 360 is narrower than the thickness d of the heat conduction member 453. In order to ensure insulation property, it is desirable that the area along the inner side of the convex portions 458 and 459 of the cooling member 340 be separated from the outer peripheries of the insulation sheets 440 and 441 by greater than or equal to 1 mm. The configuration illustrated in the first modified example also has an effect similar to that of the embodiment. Furthermore, it is not necessary to form the concave portions 604 and 605 of the die 603 in the transfer molding step, and the manufacturability of the die 603 is improved.

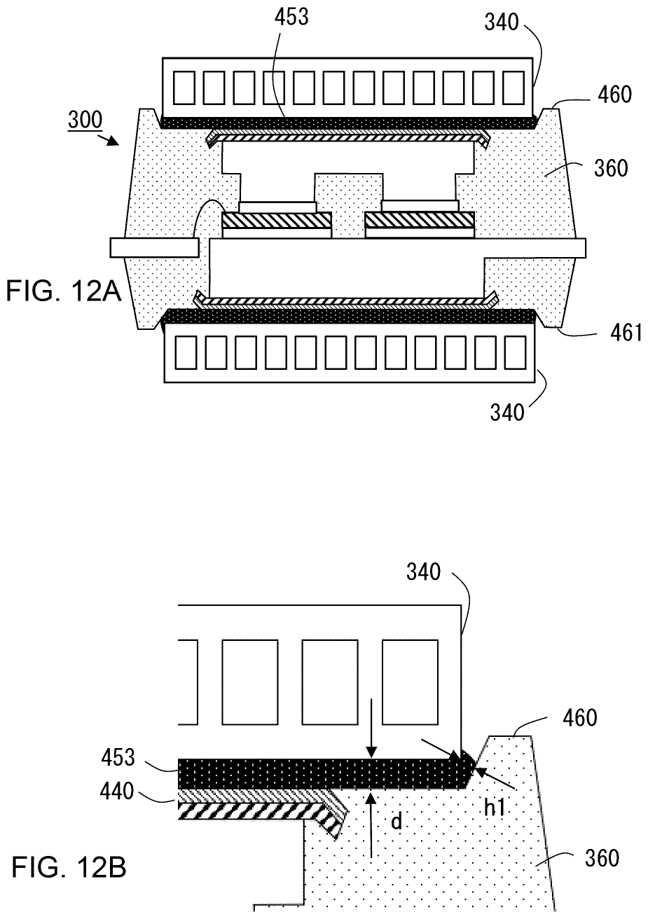

FIGS. 12(a) and 12(b) are cross-sectional views taken along line X-X of an electric circuit body 400 in a second modified example. FIG. 12(a) is an overall view, and FIG. 12(b) is a partially enlarged view. Note that a cross-sectional view taken along line Y-Y of the electric circuit body 400 is similar to that of FIG. 3.

In the embodiment illustrated in FIG. 2, the convex portions 454 and 455 formed on the sealing material 360 are formed to a height at which the tops do not reach the cooling member 340, but in the second modified example, as illustrated in FIG. 12(a), convex portions 460 and 461 are formed so as to be high in the direction of the cooling member 340 than the heat dissipating surface 301 and at a height that coves the end portion of the cooling member 340 from the outer side in the stacking direction of the semiconductor device 300 and the cooling member 340. As illustrated in FIG. 12(b), at the end portion of the cooling member 340, an interval between the convex portion 460 of the sealing material 360 and the cooling member 340 is a first interval h1. The first interval h1 between an area along the inner side of the convex portions 460 and 461 provided at the end portion of the sealing material 360 and an area along the outer side of the cooling member 340 is narrower than the thickness d of the heat conduction member 453. The configuration illustrated in the second modified example also has an effect similar to that of the embodiment. Furthermore, since the heat conduction member 453 is less likely to flow out to the outside, the thickness d of the heat conduction member 453 can be reduced, the thermal resistance is improved, and excellent heat dissipation property is obtained.

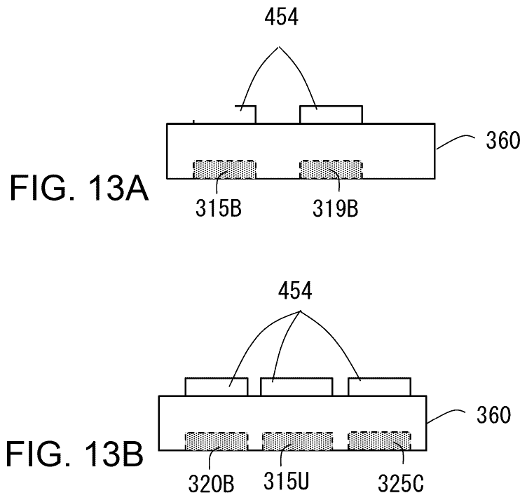

FIGS. 13(a) and 13(b) are side views of an electric circuit body 400 in a third modified example. FIG. 13(a) is a side view as viewed from one terminal side corresponding to the right side of FIG. 4, and FIG. 13(b) is a side view as viewed from the other terminal side corresponding to the left side of FIG. 4. Note that a cross-sectional view taken along line Y-Y of the electric circuit body 400 is similar to that of FIG. 3.

In the embodiment illustrated in FIG. 4, the convex portion 454 having a uniform height is formed along the side surface on the terminal side of the semiconductor device 300. In the third modified example, as illustrated in FIGS. 13(a) and 13(b), a plurality of convex portions 454 are formed in correspondence with positions of a plurality of terminals provided on a terminal side which is one side surface of the semiconductor device 300. As the plurality of convex portions 454 are located on the projection surface of the terminal, even if the heat conduction member 453 flows out to the outside of the semiconductor device 300 from between the convex portions 454 and 454, it can be prevented from adhering to the terminal. The configuration illustrated in the third modified example also has an effect similar to that of the embodiment. Note that although only one surface (emitter side) of the semiconductor device 300 has been illustrated and described, convex portions may be similarly formed on the other surface (collector side) in correspondence with the position of each terminal.

Furthermore, the configuration described in the third modified example may be applied to the first modified example and the second modified example. That is, the convex portions 458 and 459 formed facing the sealing material 360 at the end portion of the cooling member 340 on one side surface of the semiconductor device 300 from which the terminal is protruded may respectively form convex portions in correspondence with the positions of the terminals. Further, the convex portions 460 and 461 formed on the sealing material 360 on one side surface of semiconductor device 300 from which the terminal is protruded at a height that covers the end portion of the cooling member 340 from the outer side may form convex portions in correspondence with the positions of the terminals.

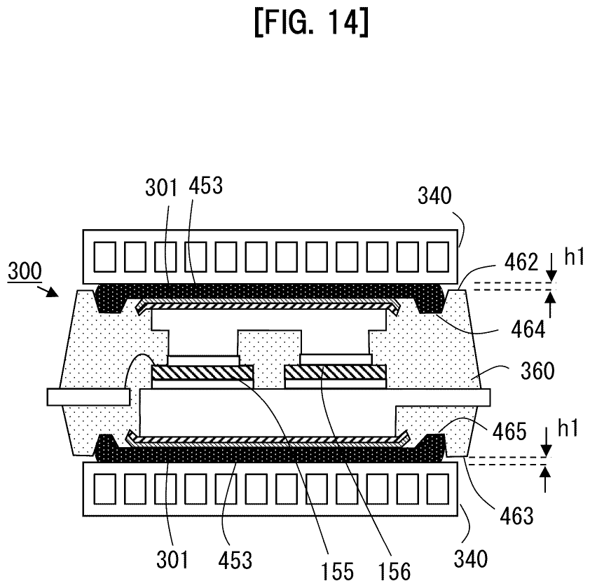

FIG. 14 is a cross-sectional view taken along line X-X of an electric circuit body 400 in a fourth modified example. Note that a cross-sectional view taken along line Y-Y of the electric circuit body 400 is similar to that of FIG. 3.

In the embodiment illustrated in FIG. 2, the convex portions 454 and 455 are formed on the sealing material 360, but in the fourth modified example, as illustrated in FIG. 14, the convex portions 462 and 463 are formed on the sealing material 360, and the concave portions 464 and 465 are formed in the sealing material 360 between the convex portions 462 and 463 and the heat dissipating surface 301. The interval between the convex portions 462 and 463 and the cooling member 340 is set to a first interval h1. The first interval h1 is narrower than the thickness d of the heat conduction member 453. The configuration illustrated in the fourth modified example also has an effect similar to that of the embodiment. Furthermore, the heat conduction member 453 is retained in the concave portions 464 and 465 of the sealing material 360 before the heat conduction member 453 flows out to the outside by the cooling/heating cycle, and as a result, the heat conduction member 453 is less likely to flow out to the outside, so that the heat conduction member 453 can be effectively prevented from adhering to the terminal.

Furthermore, the configuration described in the third modified example may be applied to the fourth modified example. That is, the convex portions 462 and 463 and the concave portions 464 and 465 formed at the sealing material 360 on one side surface of the semiconductor device 300 from which the terminal is protruded may be respectively formed in correspondence with the positions of the terminals.

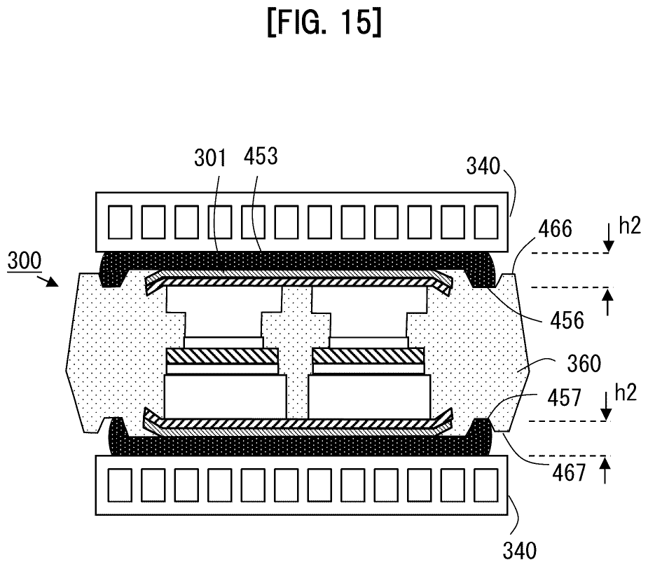

FIG. 15 is a cross-sectional view taken along line Y-Y of an electric circuit body 400 in a fifth modified example. Note that a cross-sectional view taken along line X-X of the electric circuit body 400 may be the same as that in FIG. 2, and other first to fourth modified examples may be applied.

In the embodiment illustrated in FIG. 3, the concave portions 456 and 457 are formed in the sealing material 360, but in the fifth modified example, as illustrated in FIG. 15, the convex portions 466 and 467 are formed on the sealing material 360 on the outer side of the concave portions 456 and 457. In other words, the convex portions 466 and 467 are formed on the sealing material 360, and the concave portions 456 and 457 are further formed between the convex portions 466 and 467 and the heat dissipating surface 301. The interval between the bottom portions of the concave portions 456 and 457 and the cooling member 340 is set to a second interval h2. The second interval h2 is wider than the thickness d of the heat conduction member 453. The interval between the bottom tops of the convex portions 466 and 467 and the cooling member 340 is narrower than the second interval h2. The configuration illustrated in the fifth modified example also has an effect similar to that of the embodiment. Furthermore, the heat conduction member 453 is retained in the concave portions 456 and 457 of the sealing material 360 before flowing out by the cooling/heating cycle, and even with the heat conduction member 453 having low viscosity, there is an effect of preventing the heat conduction member from flowing out to the outside.

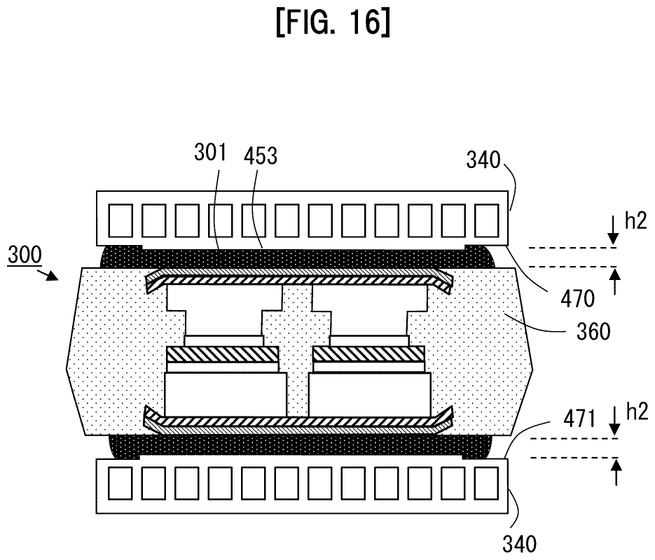

FIG. 16 is a cross-sectional view taken along line Y-Y of an electric circuit body 400 in a sixth modified example. Note that a cross-sectional view taken along line X-X of the electric circuit body 400 may be the same as that in FIG. 2, and other first to fourth modified examples may be applied.

In the embodiment illustrated in FIG. 3, the concave portions 456 and 457 are formed in the sealing material 360, but in the sixth modified example, as illustrated in FIG. 16, the concave portions 470 and 471 are formed at the end portion of the cooling member 340. An interval between the bottom portions of the concave portions 470 and 471 and the sealing material 360 is set to a second interval h2. The second interval h2 is wider than the thickness d of the heat conduction member 453. The configuration illustrated in the sixth modified example also has an effect similar to that of the embodiment. Furthermore, the heat conduction member 453 is retained between the concave portions 470 and 471 of the cooling member 340 and the sealing material 360 before flowing out by the cooling/heating cycle, and even with the heat conduction member 453 having low viscosity, there is an effect of preventing the heat conduction member from flowing out to the outside.

FIG. 17 is a circuit diagram of the power conversion device 200 using the semiconductor device 300.

The power conversion device 200 includes inverter circuit units 140 and 142, an inverter circuit unit 43 for an auxiliary equipment, and a capacitor module 500. The inverter circuit units 140 and 142 include a plurality of semiconductor devices 300, which are connected to configure a three-phase bridge circuit. In a case where the current capacity is large, the semiconductor devices 300 are further connected in parallel, and the parallel connection is performed in correspondence with each phase of the three-phase inverter circuit, thereby responding to an increase in the current capacity. In addition, it is also possible to respond to an increase in current capacity by connecting the active elements 155 and 157 and the diodes 156 and 158, which are semiconductor elements incorporated in the semiconductor device 300, in parallel.

The inverter circuit unit 140 and the inverter circuit unit 142 have the same basic circuit configuration, and basically the same control method and operation. Since an outline of a circuit operation of the inverter circuit unit 140 and the like is well known, a detailed description thereof will be omitted here.

As described above, the upper arm circuit includes the active element 155 for the upper arm and the diode 156 for the upper arm as semiconductor elements for switching, and the lower arm circuit includes the active element 157 for the lower arm and the diode 158 for the lower arm as semiconductor elements for switching. The active elements 155 and 157 perform switching operation in response to a drive signal output from one or the other of the two driver circuits constituting the driver circuit 174, and convert DC power supplied from the battery 136 into three-phase AC power.

As described above, the active element 155 for the upper arm and the active element 157 for the lower arm include a collector electrode, an emitter electrode, and a gate electrode. The diode 156 for the upper arm and the diode 158 for the lower arm include two electrodes, a cathode electrode and an anode electrode. As illustrated in FIG. 7, the cathode electrodes of the diodes 156 and 158 are electrically connected to the collector electrodes of the active elements 155 and 157, respectively, and the anode electrodes are electrically connected to the emitter electrodes of the active elements 155 and 157, respectively. As a result, the current flows in the forward direction from the emitter electrode to the collector electrode of the active element 155 for the upper arm and the active element 157 for the lower arm. The active elements 155 and 157 are, for example, IGBTs.

Note that a metal oxide semiconductor field effect transistor (MOSFET) may be used as the active element, in which case, the diode 156 for the upper arm and the diode 158 for the lower arm are unnecessary.

The positive electrode side terminal 315B and the negative electrode side terminal 319B of each of the upper and lower arm series circuits are respectively connected to a DC terminal for capacitor connection of the capacitor module 500. The AC power is generated at the connecting portion of the upper arm circuit and the lower arm circuit, and the connecting portion of the upper arm circuit and the lower arm circuit of each of the upper and lower arm series circuits is connected to the AC side terminal 320B of each semiconductor device 300. The AC side terminal 320B of each semiconductor device 300 of each phase is connected to the AC output terminal of the power conversion device 200, and the generated AC power is supplied to a stator winding of the motor generator 192 or 194.

The control circuit 172 generates a timing signal for controlling the switching timing of the active element 155 for the upper arm and the active element 157 for the lower arm based on input information from a control device, a sensor (e.g., the current sensor 180), or the like on the vehicle side. The driver circuit 174 generates a drive signal for causing the active element 155 for the upper arm and the active element 157 for the lower arm to perform the switching operation based on the timing signal output from the control circuit 172. Note that reference numerals 181, 182, and 188 denote connectors.

The upper and lower arm series circuits include a temperature sensor (not illustrated), and temperature information of the upper and lower arm series circuits is input to the microcomputer. Voltage information on the DC positive electrode side of the upper and lower arm series circuits is input to the microcomputer. The microcomputer performs overtemperature detection and overvoltage detection based on these pieces of information, stops the switching operation of all the active elements 155 for the upper arm and the active elements 157 for the lower arm when overtemperature or overvoltage is detected to protect the upper and lower arm series circuits from overtemperature or overvoltage.

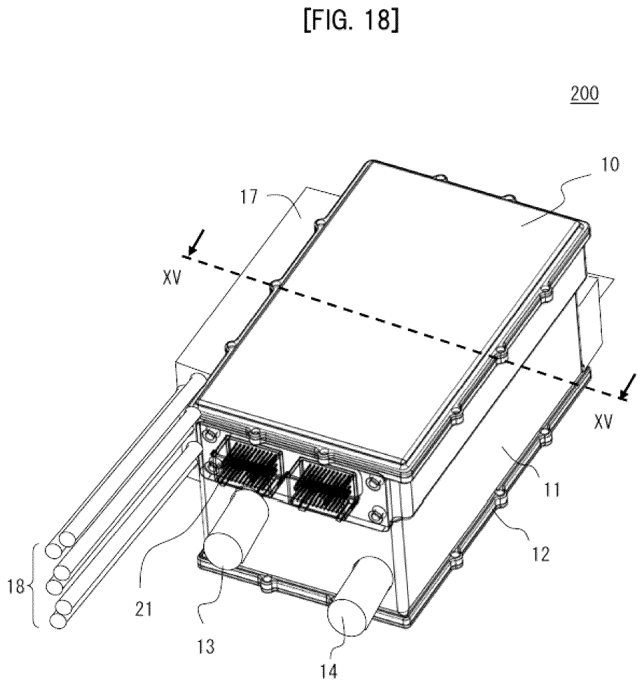

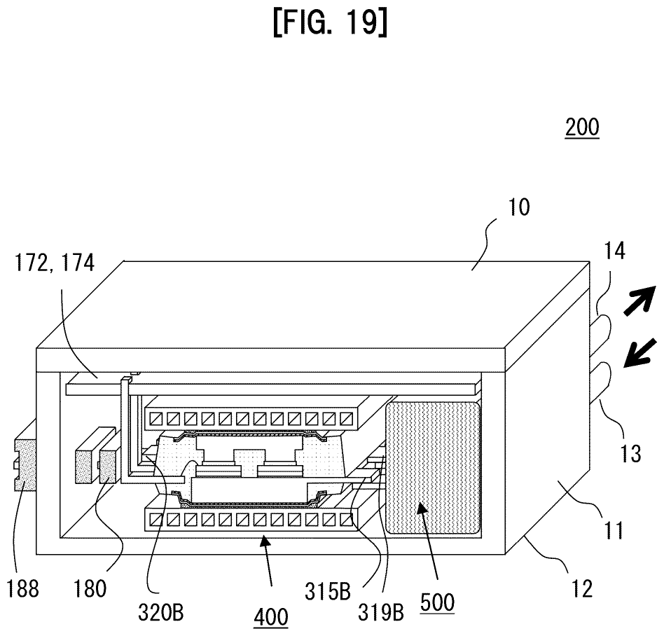

FIG. 18 is an outer appearance perspective view of the power conversion device 200 illustrated in FIG. 17, and FIG. 19 is a cross-sectional perspective view taken along line XV-XV of the power conversion device 200 illustrated in FIG. 18.

The power conversion device 200 includes a housing 12 that is configured by a lower case 11 and an upper case 10 and is formed in a substantially rectangular parallelepiped shape. An electric circuit body 400, a capacitor module 500, and the like are accommodated in the housing 12. The electric circuit body 400 has a cooling flow path flowing to the cooling member 340, and a cooling water inflow pipe 13 and a cooling water outflow pipe 14 communicating with the cooling flow path are protruded from one side surface of the housing 12. An upper side of the lower case 11 is opened, and the upper case 10 is attached to the lower case 11 while closing the opening of the lower case 11. The upper case 10 and the lower case 11 are formed of an aluminum alloy or the like, and are fixed while being sealed with respect to the outside. The upper case 10 and the lower case 11 may be integrated. Since the housing 12 has a simple rectangular parallelepiped shape, attachment to a vehicle or the like is facilitated, and production is facilitated.

A connector 17 is attached to one side surface of the housing 12 in the longitudinal direction, and an AC terminal 18 is connected to the connector 17. Furthermore, a connector 21 is provided on a surface from which the cooling water inflow pipe 13 and the cooling water outflow pipe 14 are led out.

As illustrated in FIG. 19, the electric circuit body 400 is accommodated in the housing 12. The control circuit 172 and the driver circuit 174 are disposed above the electric circuit body 400, and the capacitor module 500 is accommodated on the DC terminal side of the electric circuit body 400. The power conversion device 200 can be thinned, and the degree of freedom in installation on the vehicle is improved by disposing the capacitor module at the same height as the electric circuit body 400. The AC side terminal 320B of the electric circuit body 400 penetrates the current sensor 180 and is connected to the connector 188. Furthermore, the positive electrode side terminal 315B and the negative electrode side terminal 319B, which are DC terminals of the semiconductor device 300, are joined to the positive and negative electrode side terminals 362A and 362B of the capacitor module 500, respectively.

The embodiment described above has the following operation effect.
(1) An electric circuit body 400 includes: a semiconductor device 300 incorporating semiconductor elements 155 and 157 by sealing with a sealing material 360 and having a heat dissipating surface 301 for dissipating heat of the semiconductor elements 155 and 157, the heat dissipating surface 301 being formed on at least one surface, a cooling member 340 disposed facing the heat dissipating surface 301 of the semiconductor device 300 and configured to cool the semiconductor elements 155 and 157, and a heat conduction member 453 disposed between the semiconductor device 300 and the cooling member 340, where a terminal connected to the semiconductor elements 155 and 157 protrudes out from at least one side surface of the semiconductor device 300, and a first interval h1 between the sealing material 360 and the cooling member 340 on one side surface of the semiconductor device 300 from which the terminal is protruded is narrower than a second interval h2 between the sealing material 360 and the cooling member 340 on the other side surface of the semiconductor device 300 from which the terminal is not protruded. As a result, it is possible to suppress the outflow of the heat conduction member and to provide a highly reliable device.

The present invention is not limited to the embodiments described above, and other modes conceivable within the scope of the technical idea of the present invention are also included in the scope of the present invention as long the characteristics of the present invention are not impaired. In addition, the embodiment described above and a plurality of modified examples may be combined.

### REFERENCE SIGNS LIST

10 upper case
11 lower case
13 cooling water inflow pipe
14 cooling water outflow pipe
17, 21, 181, 182, 188 connector
18 AC terminal
43, 140, 142 inverter circuit unit
155 first semiconductor element (upper arm circuit active element)
156 first semiconductor element (upper arm circuit diode)
157 second semiconductor element (lower arm circuit active element)
158 second semiconductor element (lower arm circuit diode)
172 control circuit
174 driver circuit
180 current sensor
192, 194 motor generator
200 power conversion device
300 semiconductor device
301 heat dissipating surface
315B positive electrode side terminal
319B negative electrode side terminal
320B AC side terminal
325E emitter sense terminal
325L lower arm gate terminal
325C collector sense terminal
325U upper arm gate terminal
340 cooling member
360 sealing material
400 electric circuit body
420 conductor plate
430 first conductor plate (upper arm circuit emitter side)
431 second conductor plate (upper arm circuit collector side)
432 third conductor plate (lower arm circuit emitter side)
433 fourth conductor plate (lower arm circuit collector side)
440 first insulation sheet (emitter side)
441 second insulation sheet (collector side)
442 first resin insulating layer (emitter side)
443 second resin insulating layer (collector side)
444 metal foil
450 projection region of conductor plate
453 heat conduction member
454, 460, 462, 466 convex portion of sealing material on emitter side
455, 461, 463, 467 convex portion of sealing material on collector side
456, 464 concave portion of sealing material on emitter side
457, 465 concave portion of sealing material on collector side
458 convex portion of cooling member on emitter side
459 convex portion of cooling member on collector side
470 concave portion of cooling member on emitter side
471 concave portion of cooling member on collector side
500 capacitor module
601 transfer molding device
602 spring

1. An electric circuit body comprising:
a semiconductor device incorporating a semiconductor element by sealing with a sealing material and having a heat dissipating surface for dissipating heat of the semiconductor element, the heat dissipating surface being formed on at least one surface;
a cooling member disposed facing the heat dissipating surface of the semiconductor device and configured to cool the semiconductor element; and
a heat conduction member disposed between the semiconductor device and the cooling member,
wherein
a terminal connected to the semiconductor element protrudes out from at least one side surface of the semiconductor device, and
a first interval between the sealing material and the cooling member on the one side surface of the semiconductor device from which the terminal is protruded is narrower than a second interval between the sealing material and the cooling member on the other side surface of the semiconductor device from which the terminal is not protruded.

2. The electric circuit body according to claim 1, wherein the first interval is less than or equal to a thickness of the heat conduction member, and when the second interval is wider than the thickness of the heat conduction member, the first interval is equal to the thickness of the heat conduction member.

3. The electric circuit body according to claim 1, wherein the second interval is greater than or equal to a thickness of the heat conduction member, and when the first interval is narrower than the thickness of the heat conduction member, the second interval is equal to the thickness of the heat conduction member.

4. The electric circuit body according to claim 1, wherein
a convex portion protruding out from a surface of the heat dissipating surface is formed on the sealing material on the one side surface of the semiconductor device from which the terminal is protruded, and
an interval between the convex portion and the cooling member is the first interval.

5. The electric circuit body according to claim 4, wherein the convex portion is formed at a height covering an end portion of the cooling member from outer side.

6. The electric circuit body according to claim 5, wherein a concave portion is formed in the sealing material between the convex portion and the heat dissipating surface.

7. The electric circuit body according to claim 1, wherein
a convex portion facing the sealing material is formed at an end portion of the cooling member on the one side surface of the semiconductor device from which the terminal is protruded, and
an interval between the convex portion and the cooling member is the first interval.

8. The electric circuit body according to claim 4, wherein
the terminal includes a plurality of terminals, and
a plurality of the convex portions are formed in correspondence with positions of the plurality of terminals.

9. The electric circuit body according to claim 4, wherein
a concave portion recessed from the heat dissipating surface is formed in the sealing material on the other side surface of the semiconductor device from which the terminal is not protruded, and
an interval between the concave portion and the cooling member is the second interval.

10. The electric circuit body according to claim 9, wherein a convex portion is formed on the sealing material on the other side surface of the semiconductor device on the outer side of the concave portion.

11. The electric circuit body according to claim 4, wherein
a concave portion is formed at an end portion of the cooling member on the other side surface of the semiconductor device from which the terminal is not protruded, and
an interval between the concave portion and the sealing material is the second interval.

12. The electric circuit body according to claim 1, wherein a thermal conductivity of the heat conduction member is 5 to 8 W/(m·K).

13. The electric circuit body according to claim 1, wherein
the semiconductor device includes a conductor plate joined to the semiconductor element, and
the semiconductor device includes an insulation sheet between the conductor plate and the heat conduction member.

14. The electric circuit body according to claim 9, wherein
the heat dissipating surface is formed on both surfaces of the semiconductor element,
the cooling member is disposed on both surfaces of the semiconductor device facing the heat dissipating surface, and
the heat conduction member is disposed on both surfaces between the semiconductor device and the cooling member.

15. A power conversion device comprising the electric circuit body according to claim 1, wherein DC power is converted into AC power.
